(19) United States
(12) Patent Application Publication
(10) Pub. No.: US 2026/0089920 A1
(43) Pub. Date: Mar. 26, 2026

(54) SEMICONDUCTOR DEVICE AND SEMICONDUCTOR STORAGE DEVICE

(71) Applicant: Kioxia Corporation, Tokyo (JP)

(72) Inventor: Yu KATAKURA, Yokkaichi (JP)

(73) Assignee: Kioxia Corporation, Tokyo (JP)

(21) Appl. No.: 19/077,477

(22) Filed: Mar. 12, 2025

(30) Foreign Application Priority Data
Sep. 20, 2024 (JP) 2024-163635

(51) Int. Cl. H10B 12/00

(52) U.S. Cl. CPC H10B 12/33; H10B 12/05

(57) ABSTRACT

A semiconductor device includes a first electrode; a second electrode; an oxide semiconductor layer extending between the first electrode and the second electrode; and a gate electrode provided next to the oxide semiconductor layer. The first electrode includes a first region, a second region, and a third region. The first region is provided between the second region and the oxide semiconductor layer, and includes at least one of In, Sn, Zn, Ta, or W. The second region includes a second metal element and includes or does not include N, and the second metal element includes one of Ti, W, Mo or Ta. The third region includes a first part and a second part, the third region includes a first element and O, and the first element includes at least one of Ti, Al, Zr, Hf, or Si.

### CROSS-REFERENCE TO RELATED APPLICATION

This application is based upon and claims the benefit of priority from Japanese Patent Application No. 2024-163635, filed Sep. 20, 2024, the entire contents of which are incorporated herein by reference.

### FIELD

Embodiments described herein relate generally to a semiconductor device and a semiconductor storage device.

### BACKGROUND

An oxide semiconductor transistor having a channel formed in an oxide semiconductor layer has an excellent characteristic of very low channel leakage current during off-operation. Therefore, for example, the oxide semiconductor transistor is applicable to a switching transistor of a memory cell of dynamic random access memory (DRAM).

### DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a schematic cross-sectional view illustrating an example of a method for manufacturing the semiconductor device according to the first embodiment;

FIG. 6 is a schematic cross-sectional view illustrating an example of the method for manufacturing the semiconductor device according to the first embodiment;

FIG. 7 is a schematic cross-sectional view illustrating an example of the method for manufacturing the semiconductor device according to the first embodiment;

FIG. 8 is a schematic cross-sectional view illustrating an example of the method for manufacturing the semiconductor device according to the first embodiment;

FIG. 9 is a schematic cross-sectional view illustrating an example of the method for manufacturing the semiconductor device according to the first embodiment;

FIG. 10 is a schematic cross-sectional view illustrating an example of the method for manufacturing the semiconductor device according to the first embodiment;

FIG. 11 is a schematic cross-sectional view illustrating an example of the method for manufacturing the semiconductor device according to the first embodiment;

FIG. 12 is a schematic cross-sectional view illustrating an example of the method for manufacturing the semiconductor device according to the first embodiment;

FIG. 13 is a schematic cross-sectional view illustrating an example of the method for manufacturing the semiconductor device according to the first embodiment;

FIG. 14 is a schematic cross-sectional view illustrating an example of the method for manufacturing the semiconductor device according to the first embodiment;

FIG. 15 is a schematic cross-sectional view illustrating a semiconductor device according to a first comparative example;

FIG. 16 is a schematic cross-sectional view illustrating a semiconductor device according to a second comparative example;

FIG. 17 is a schematic cross-sectional view illustrating a semiconductor device according to a second embodiment;

FIG. 18 is an equivalent circuit diagram illustrating a semiconductor storage device according to a third embodiment; and

FIG. 19 is a schematic cross-sectional view illustrating the semiconductor storage device according to the third embodiment.

### DETAILED DESCRIPTION

Embodiments provide a semiconductor device with a transistor having excellent characteristics.

In general, according to one embodiment, a semiconductor device includes a first electrode; a second electrode; an oxide semiconductor layer extending between the first electrode and the second electrode along a first direction; a gate electrode provided next to the oxide semiconductor layer; and a gate insulation layer provided between the gate electrode and the oxide semiconductor layer. The first electrode includes a first region, a second region, and a third region. The first region is provided between the second region and the oxide semiconductor layer, and includes a first metal element and oxygen (O), and the first metal element includes at least one of indium (In), tin (Sn), zinc (Zn), tantalum (Ta) or tungsten (W). The second region includes a second metal element and contains or does not contain nitrogen (N), and the second metal element includes one of titanium (Ti), tungsten (W), molybdenum (Mo) or tantalum (Ta). The third region is in contact with the first region and the second region and includes a first part and a second part, the second region is provided between the first part and the second part in a second direction perpendicular to the first direction, the third region includes a first element and oxygen (O), and the first element includes at least one of titanium (Ti), aluminum (Al), zirconium (Zr), hafnium (Hf), or silicon (Si).

Hereinbelow, embodiments will be described with reference to the drawings. In the following description, the same or similar members will be denoted by the same reference numerals, and description for the members described once may be omitted as appropriate.

Further, the terms “up”, “down”, “upper”, “lower”, “upward”, or “downward” may be used herein for convenience of description. “up”, “down”, “upper”, “lower”, “upward”, or “downward” are the terms that indicate relative positional relationships in the drawings, and are not the terms that define positional relationships with respect to gravity.

The qualitative and quantitative analyses on the chemical compositions of the members of a semiconductor device and a semiconductor storage device described herein may be performed by, for example, Secondary Ion Mass Spectrometry (SIMS), Energy Dispersive X-ray Spectroscopy (EDX), and Rutherford Back-Scattering Spectroscopy (RBS). Further, for example, Transmission Electron Microscope (TEM) may be used for measuring a thickness of the members of the semiconductor device and the semiconductor storage device, a distance between the members, a crystal grain size, or the like.

### First Embodiment

A semiconductor device according to a first embodiment includes a first electrode, a second electrode, an oxide semiconductor layer provided between the first electrode and the second electrode, a gate electrode opposite to the oxide semiconductor layer, and a gate insulation layer provided between the gate electrode and the oxide semiconductor layer. The first electrode includes a first region, a second region, and a third region. The first region is provided between the second region and the oxide semiconductor layer, is in contact with the oxide semiconductor layer and the second region, and contains a first metal element and oxygen (O), and the first metal element is at least one element selected from a group including indium (In), tin (Sn), zinc (Zn), tantalum (Ta) and tungsten (W). The second region contains a second metal element and contains or does not contain nitrogen (N), and the second metal element is one element selected from a group including titanium (Ti), tungsten (W), molybdenum (Mo) and tantalum (Ta). The third region is in contact with the first region and the second region and includes a first part and a second part, the second region is provided between the first part and the second part in a second direction perpendicular to a first direction connecting the first electrode and the second electrode, the third region contains a first element and oxygen (O), and the first element is at least one element selected from a group including titanium (Ti), aluminum (Al), zirconium (Zr), hafnium (Hf) and silicon (Si).

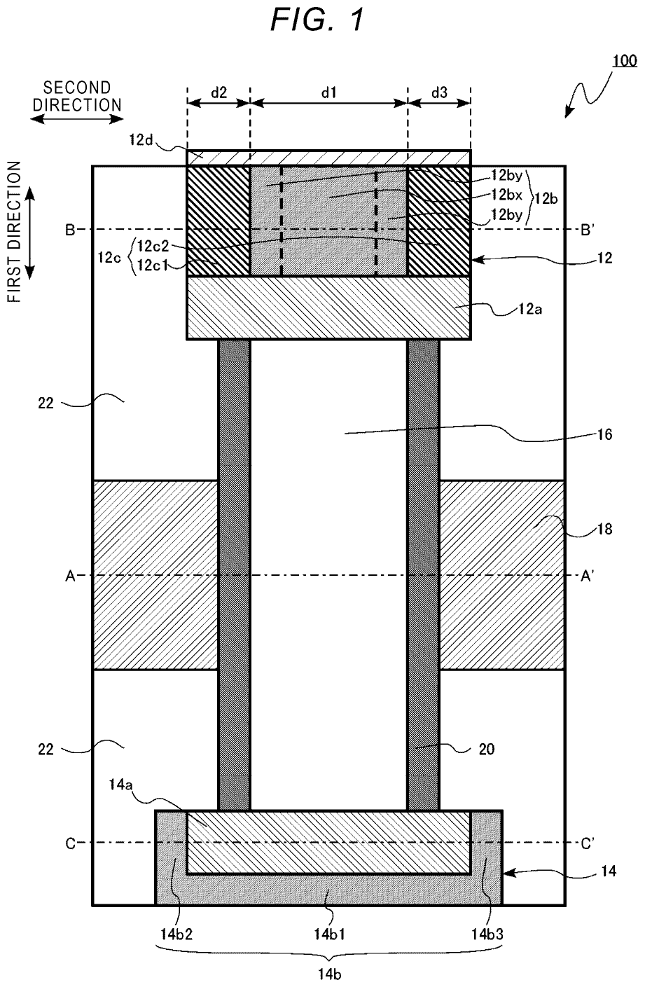

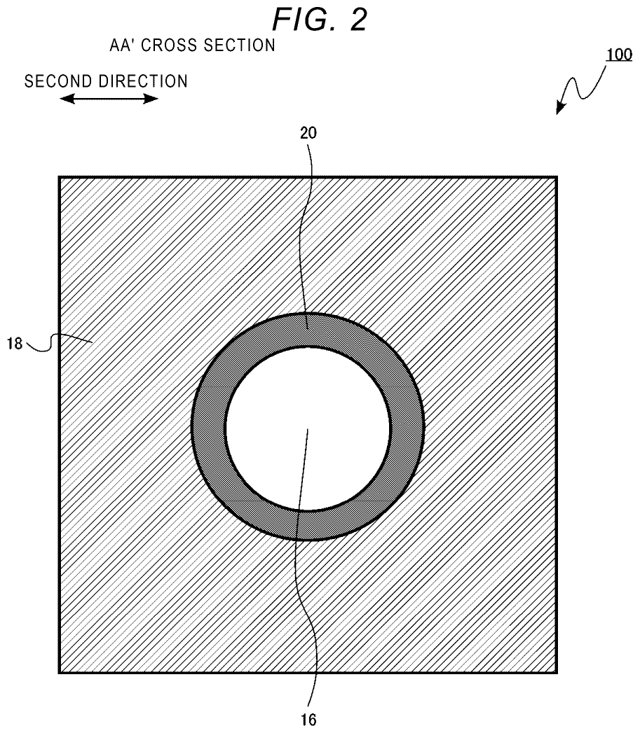

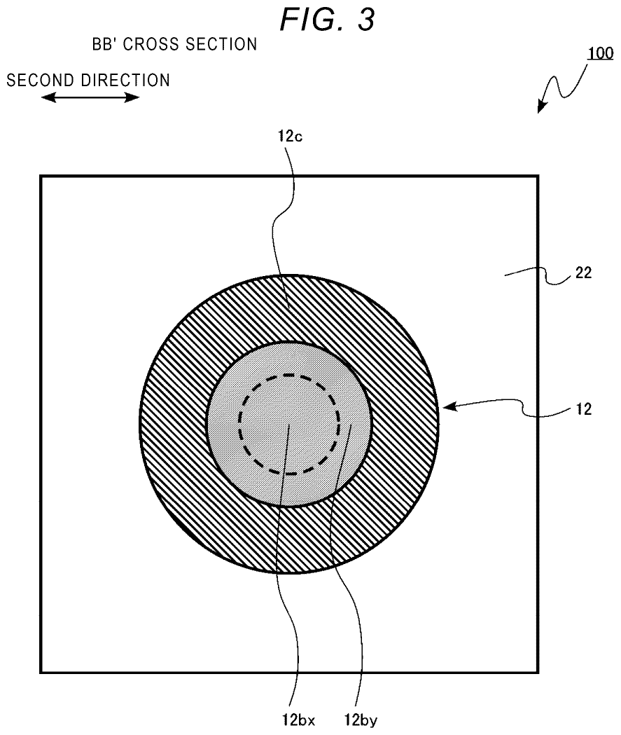

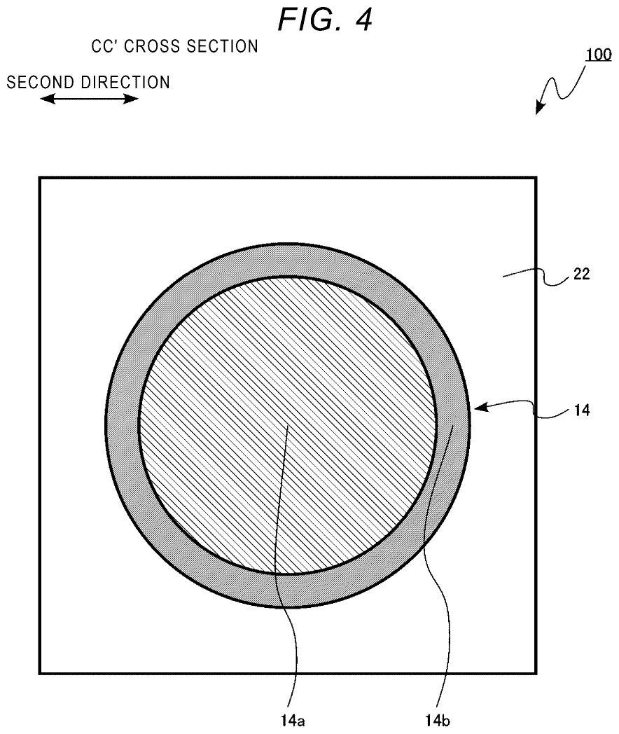

FIGS. 1, 2, 3, and 4 are schematic cross-sectional views illustrating the semiconductor device according to the first embodiment. FIG. 2 is a cross-sectional view taken along line AA′ of FIG. 1. FIG. 3 is a cross-sectional view taken along line BB′ of FIG. 1. FIG. 4 is a cross-sectional view taken along line CC′ of FIG. 1. In FIG. 1, a vertical direction is referred to as a first direction. In FIG. 1, a horizontal direction is referred to as a second direction. The second direction is perpendicular to the first direction.

The semiconductor device according to the first embodiment is a transistor 100. The transistor 100 is an oxide semiconductor transistor in which a channel is formed in an oxide semiconductor. In the transistor 100, a gate electrode is provided, surrounding the oxide semiconductor layer where the channel is formed. The transistor 100 is a so-called Surrounding Gate Transistor (SGT). The transistor 100 is a so-called vertical transistor.

The transistor 100 includes an upper electrode 12, a lower electrode 14, an oxide semiconductor layer 16, a gate electrode 18, a gate insulation layer 20, and an interlayer insulating layer 22. The upper electrode 12 includes a first metal oxide region 12a, a first metal region 12b, a sidewall region 12c, and an upper region 12d. The first metal region 12b includes an internal region 12bx and an external region 12by. The sidewall region 12c includes a first part 12c1 and a second part 12c2. The lower electrode 14 includes a second metal oxide region 14a and a second metal region 14b. The second metal region 14b includes a third part 14b1, a fourth part 14b2, and a fifth part 14b3.

The upper electrode 12 is an example of the first electrode. The first metal oxide region 12a is an example of the first region. The first metal region 12b is an example of the second region. The sidewall region 12c is an example of the third region. The upper region 12d is an example of a fourth region.

The lower electrode 14 is an example of the second electrode. The second metal oxide region 14a is an example of a fifth region. The second metal region 14b is an example of a sixth region.

The upper electrode 12 is provided on the oxide semiconductor layer 16. The upper electrode 12 is electrically connected to the oxide semiconductor layer 16. For example, the upper electrode 12 is in contact with the oxide semiconductor layer 16. The upper electrode 12 serves as a source electrode or a drain electrode of the transistor 100.

The lower electrode 14 is provided below the oxide semiconductor layer 16. The lower electrode 14 is electrically connected to the oxide semiconductor layer 16. For example, the lower electrode 14 is in contact with the oxide semiconductor layer 16. The lower electrode 14 serves as a source electrode or a drain electrode of the transistor 100.

The oxide semiconductor layer 16 is provided between the upper electrode 12 and the lower electrode 14. For example, the oxide semiconductor layer 16 is in contact with the upper electrode 12. The oxide semiconductor layer 16 is in contact with the lower electrode 14.

A channel is formed in the oxide semiconductor layer 16 to serve as a current path during on-operation of the transistor 100.

The oxide semiconductor layer 16 is an oxide semiconductor. For example, the oxide semiconductor layer 16 is amorphous.

For example, the oxide semiconductor layer 16 contains at least one element selected from a group including indium (In), gallium (Ga), silicon (Si), aluminum (Al), and tin (Sn) with zinc (Zn) and oxygen (O). For example, the oxide semiconductor layer 16 contains indium (In), gallium (Ga), zinc (Zn) and oxygen (O). For example, the oxide semiconductor layer 16 contains indium gallium zinc oxide. For example, the oxide semiconductor layer 16 is an indium gallium zinc oxide layer.

For example, the oxide semiconductor layer 16 contains at least one element selected from a group including titanium (Ti), zinc (Zn), and tungsten (W), and oxygen (O). For example, the oxide semiconductor layer 16 contains titanium oxide, zinc oxide, or tungsten oxide. For example, the oxide semiconductor layer 16 is a titanium oxide layer, a zinc oxide layer, or a tungsten oxide layer.

For example, the oxide semiconductor layer 16 includes oxygen vacancies. The oxygen vacancies in the oxide semiconductor layer 16 serve as donors.

For example, the length of the oxide semiconductor layer 16 in the first direction is 80 nm or more and 200 nm or less. For example, the length of the oxide semiconductor layer 16 in the second direction is 10 nm or more and 50 nm or less.

The first direction is a direction connecting the upper electrode 12 and the lower electrode 14. The second direction is a direction perpendicular to the first direction.

The gate electrode 18 is opposite to the oxide semiconductor layer 16. The gate electrode 18 is provided such that a position coordinate of the gate electrode 18 in the first direction corresponds to a value between position coordinates of each of the upper electrode 12 and the lower electrode 14 in the first direction.

As illustrated in FIG. 2, the gate electrode 18 surrounds the oxide semiconductor layer 16 in a cross-section perpendicular to the first direction. The gate electrode 18 is provided on a circumference of the oxide semiconductor layer 16.

The gate electrode 18 is a conductor. For example, the gate electrode 18 is a metal, a metal compound, or a semiconductor. For example, the gate electrode 18 contains tungsten (W). For example, the gate electrode 18 includes a tungsten layer.

For example, the length of the gate electrode 18 in the first direction is 20 nm or more and 100 nm or less.

The gate insulation layer 20 is provided between the oxide semiconductor layer 16 and the gate electrode 18. As illustrated in FIG. 2, the gate insulation layer 20 surrounds the oxide semiconductor layer 16 in a cross-section perpendicular to the first direction. The gate insulation layer 20 is provided between the upper electrode 12 and the lower electrode 14. For example, the gate insulation layer 20 is in contact with the upper electrode 12 and the lower electrode 14.

For example, the gate insulation layer 20 contains silicon (Si) and nitrogen (N). For example, the gate insulation layer 20 contains silicon nitride.

For example, the gate insulation layer 20 contains silicon (Si) and oxygen (O). For example, the gate insulation layer 20 contains silicon oxide.

For example, the gate insulation layer 20 is a stacked film including a silicon oxide film and a silicon nitride film.

For example, the thickness of the gate insulation layer 20 is 2 nm or more and 10 nm or less.

For example, the interlayer insulating layer 22 surrounds the upper electrode 12, the lower electrode 14, the oxide semiconductor layer 16, and the gate insulation layer 20. For example, the interlayer insulating layer 22 is provided between the upper electrode 12 and the gate electrode 18. For example, the interlayer insulating layer 22 is provided between the lower electrode 14 and the gate electrode 18.

For example, in a cross-section perpendicular to the first direction, the interlayer insulating layer 22 surrounds the upper electrode 12. For example, the interlayer insulating layer 22 surrounds the sidewall region 12c of the upper electrode 12. For example, the interlayer insulating layer 22 is in contact with the sidewall region 12c.

The interlayer insulating layer 22 is an insulator. For example, the interlayer insulating layer 22 is oxide, nitride, or oxynitride. For example, the interlayer insulating layer 22 contains silicon (Si) and oxygen (O). For example, the interlayer insulating layer 22 contains silicon oxide. For example, the interlayer insulating layer 22 is silicon oxide.

For example, the chemical composition of the interlayer insulating layer 22 is different from the chemical composition of the sidewall region 12c of the upper electrode 12.

The upper electrode 12 includes the first metal oxide region 12a, the first metal region 12b, the sidewall region 12c, and the upper region 12d.

The first metal oxide region 12a is provided between the oxide semiconductor layer 16 and the first metal region 12b. The first metal oxide region 12a is in contact with the oxide semiconductor layer 16 and the first metal region 12b.

The first metal oxide region 12a is a conductor. The first metal oxide region 12a contains a conductive metal oxide.

The first metal oxide region 12a contains the first metal element and oxygen (O). The first metal element is at least one element selected from a group including indium (In), tin (Sn), zinc (Zn), tantalum (Ta) and tungsten (W).

For example, the first metal oxide region 12a contains indium tin oxide, tin oxide, zinc oxide, tantalum-containing tin oxide or tungsten-containing tin oxide. For example, the first metal oxide region 12a is indium tin oxide, tin oxide, zinc oxide, tantalum-containing tin oxide or tungsten-containing tin oxide.

For example, indium (In) and tin (Sn) are the first metal elements. For example, the first metal oxide region 12a contains indium tin oxide. For example, the first metal oxide region 12a is indium tin oxide.

For example, the thickness of the first metal oxide region 12a in the first direction is 5 nm or more and 20 nm or less.

The first metal region 12b is provided on the first metal oxide region 12a.

The first metal region 12b is a conductor. The first metal region 12b contains a metal or a metal compound.

The first metal region 12b contains the second metal element. Further, the first metal region 12b may or may not contain nitrogen (N). The first metal region 12b may or may not contain oxygen (O). The second metal element is one element selected from a group including titanium (Ti), tungsten (W), molybdenum (Mo) and tantalum (Ta).

For example, the first metal region 12b contains titanium nitride, tungsten nitride, molybdenum nitride, tantalum nitride, tungsten, or molybdenum. For example, the first metal region 12b is titanium nitride, tungsten nitride, molybdenum nitride, tantalum nitride, tungsten or molybdenum.

For example, the second metal element is titanium (Ti). For example, the first metal region 12b contains nitrogen (N). For example, the first metal region 12b contains titanium nitride. For example, the first metal region 12b is titanium nitride.

The first metal region 12b includes the internal region 12bx and the external region 12by. As illustrated in FIG. 1, in a cross-section parallel to the first direction, the internal region 12bx is provided between a part of the external region 12by and another part of the external region 12by. As illustrated in FIG. 3, in a cross-section perpendicular to the first direction, the external region 12by surrounds the internal region 12bx.

For example, the external region 12by contains oxygen (O). For example, the internal region 12bx may or may not contain oxygen (O). An oxygen concentration in the external region 12by is higher than the oxygen concentration in the internal region 12bx. For example, the oxygen concentration of the first metal region 12b monotonically decreases in a direction from the external region 12by toward the internal region 12bx.

For example, the thickness of the first metal region 12b in the first direction is 5 nm or more and 50 nm or less. For example, a length (d1 in FIG. 1) of the first metal region 12b in the second direction is 10 nm or more and 50 nm or less.

The sidewall region 12c is provided on the first metal oxide region 12a. The sidewall region 12c is in contact with the first metal oxide region 12a and the first metal region 12b.

As illustrated in FIG. 1, the sidewall region 12c includes the first part 12c1 and the second part 12c2. The first metal region 12b is provided between the first part 12c1 and the second part 12c2 in the second direction. As illustrated in FIG. 3, the sidewall region 12c surrounds the first metal region 12b.

The sidewall region 12c is an insulator or a conductor. For example, the sidewall region 12c contains oxide.

The sidewall region 12c contains a first element and oxygen (O). The first element is at least one element selected from a group including titanium (Ti), aluminum (Al), zirconium (Zr), hafnium (Hf) and silicon (Si).

For example, the sidewall region 12c contains titanium oxide, aluminum oxide, zirconium oxide, hafnium oxide, or silicon oxide. For example, the sidewall region 12c is titanium oxide, aluminum oxide, zirconium oxide, hafnium oxide, or silicon oxide.

For example, the first element is titanium (Ti). For example, the sidewall region 12c contains titanium oxide. For example, the sidewall region 12c is titanium oxide.

For example, the first element is silicon (Si). For example, the sidewall region 12c contains silicon oxide. For example, the sidewall region 12c is silicon oxide.

For example, when the first element is silicon (Si) and the interlayer insulating layer 22 contains silicon (Si) and oxygen (O), the density of the sidewall region 12c is higher than the density of the interlayer insulating layer 22. For example, when the sidewall region 12c contains silicon oxide and the interlayer insulating layer 22 contains silicon oxide, the density of silicon oxide in the sidewall region 12c is higher than the density of silicon oxide in the interlayer insulating layer 22.

For example, the thickness of the sidewall region 12c in the first direction is 5 nm or more and 50 nm or less. For example, a length (d2 in FIG. 1) of the first part 12c1 of the sidewall region 12c in the second direction is at least one-fourth and at most three-fourths of the length (d1 in FIG. 1) of the first metal region 12b in the second direction. For example, a length (d3 in FIG. 1) of the second part 12c2 of the sidewall region 12c in the second direction is at least one-fourth and at most three-fourths of the length (d1 in FIG. 1) of the first metal region 12b in the second direction.

The upper region 12d is provided on the first metal region 12b. The first metal region 12b is provided between the first metal oxide region 12a and the upper region 12d. The upper region 12d is in contact with the first metal region 12b.

The sidewall region 12c is provided between the first metal oxide region 12a and the upper region 12d. The upper region 12d is in contact with the sidewall region 12c.

The upper region 12d is a conductor. The upper region 12d contains a metal or a metal compound.

The upper region 12d contains tungsten (W) or titanium (Ti). For example, the upper region 12d contains tungsten or titanium nitride. For example, the upper region 12d is tungsten or titanium nitride.

The lower electrode 14 includes the second metal oxide region 14a and the second metal region 14b.

The second metal oxide region 14a is provided between the oxide semiconductor layer 16 and the second metal region 14b. The second metal oxide region 14a is in contact with the oxide semiconductor layer 16 and the second metal region 14b.

The second metal oxide region 14a is a conductor. The second metal oxide region 14a contains a conductive metal oxide.

The second metal oxide region 14a contains a third metal element and oxygen (O). The third metal element is at least one element selected from a group including indium (In), tin (Sn), zinc (Zn), tantalum (Ta) and tungsten (W).

For example, the second metal oxide region 14a contains indium tin oxide, tin oxide, zinc oxide, tantalum-containing tin oxide or tungsten-containing tin oxide. For example, the second metal oxide region 14a is indium tin oxide, tin oxide, zinc oxide, tantalum-containing tin oxide or tungsten-containing tin oxide.

For example, the third metal element is indium (In) and tin (Sn). For example, the second metal oxide region 14a contains indium tin oxide. For example, the second metal oxide region 14a is indium tin oxide.

For example, the third metal element is the same element as the first metal element of the first metal oxide region 12a.

For example, the thickness of the second metal oxide region 14a in the first direction is 5 nm or more and 20 nm or less.

The second metal region 14b is provided below the second metal oxide region 14a. The second metal region 14b includes the third part 14b1, the fourth part 14b2, and the fifth part 14b3.

The second metal oxide region 14a is provided between the third part 14b1 and the oxide semiconductor layer 16. The second metal oxide region 14a is provided between the fourth part 14b2 and the fifth part 14b3 in the second direction. The second metal oxide region 14a is in contact with the third part 14b1, the fourth part 14b2, and the fifth part 14b3.

As illustrated in FIG. 4, the second metal oxide region 14a is surrounded by the second metal region 14b in a cross-section perpendicular to the first direction.

The second metal region 14b is a conductor. The second metal region 14b contains a metal or a metal compound.

The second metal region 14b contains a fourth metal element. Further, the second metal region 14b may or may not contain nitrogen (N). The second metal region 14b may or may not contain oxygen (O). The fourth metal element is one element selected from a group including titanium (Ti), tungsten (W), molybdenum (Mo) and tantalum (Ta).

For example, the second metal region 14b contains titanium nitride, tungsten nitride, molybdenum nitride, tantalum nitride, tungsten, or molybdenum. For example, the second metal region 14b is titanium nitride, tungsten nitride, molybdenum nitride, tantalum nitride, tungsten or molybdenum.

For example, the fourth metal element is titanium (Ti). For example, the second metal region 14b contains nitrogen (N). For example, the second metal region 14b contains titanium nitride. For example, the second metal region 14b is titanium nitride.

For example, the fourth metal element is the same element as the second metal element of the first metal region 12b.

Next, an example of a method for manufacturing the semiconductor device according to the first embodiment will be described.

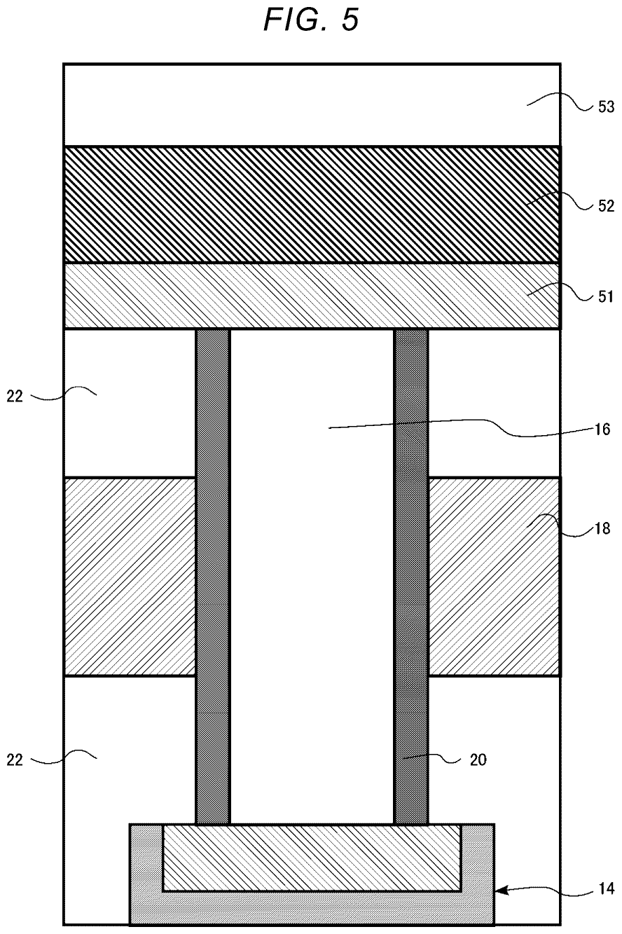

FIGS. 5, 6, 7, 8, 9, 10, 11, 12, 13, and 14 are schematic cross-sectional views illustrating an example of the method for manufacturing the semiconductor device according to the first embodiment. FIGS. 5 to 14 illustrate cross-sections corresponding to FIG. 1, respectively. FIGS. 5 to 14 are views illustrating an example of a method for manufacturing the transistor 100.

As an example, a case will be described in which the first metal oxide region 12a of the upper electrode 12 is indium tin oxide, the first metal region 12b is titanium nitride, the sidewall region 12c is titanium oxide, the upper region 12d is tungsten, and the interlayer insulating layer 22 is silicon oxide.

First, the lower electrode 14, the oxide semiconductor layer 16, the gate insulation layer 20, the gate electrode 18 and the interlayer insulating layer 22 are formed on a substrate (not illustrated) by a known manufacturing method.

An indium tin oxide film 51, a titanium oxide film 52, and a silicon nitride film 53 are formed in this order (FIG. 5). For example, the indium tin oxide film 51 and the titanium oxide film 52 are formed by a sputtering method. For example, the silicon nitride film 53 is formed by Chemical Vapor Deposition (CVD) method.

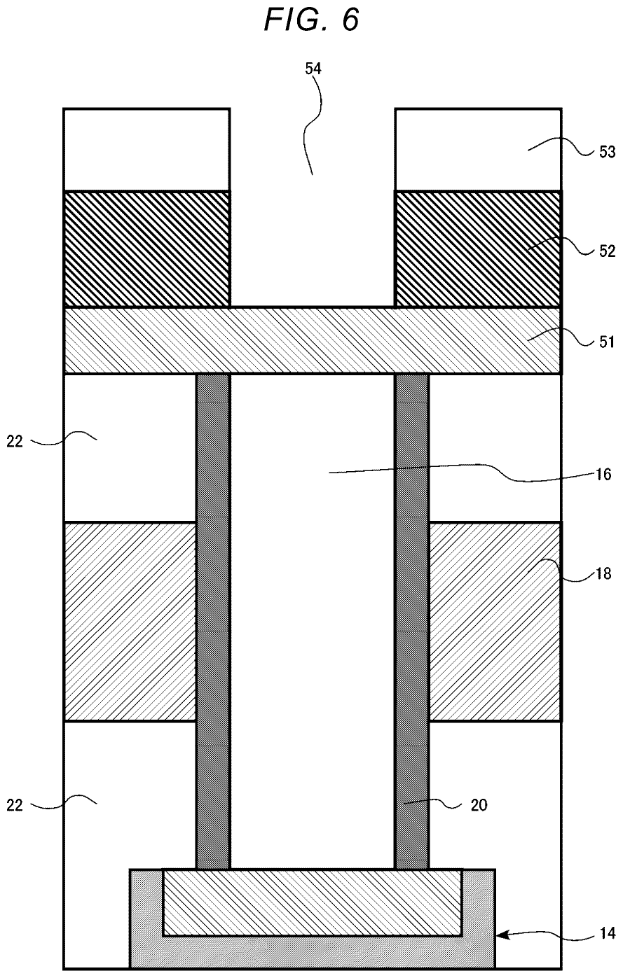

An opening 54 is formed in the silicon nitride film 53 and the titanium oxide film 52 (FIG. 6). For example, the opening 54 is formed using lithography and Reactive Ion Etching (RIE) method.

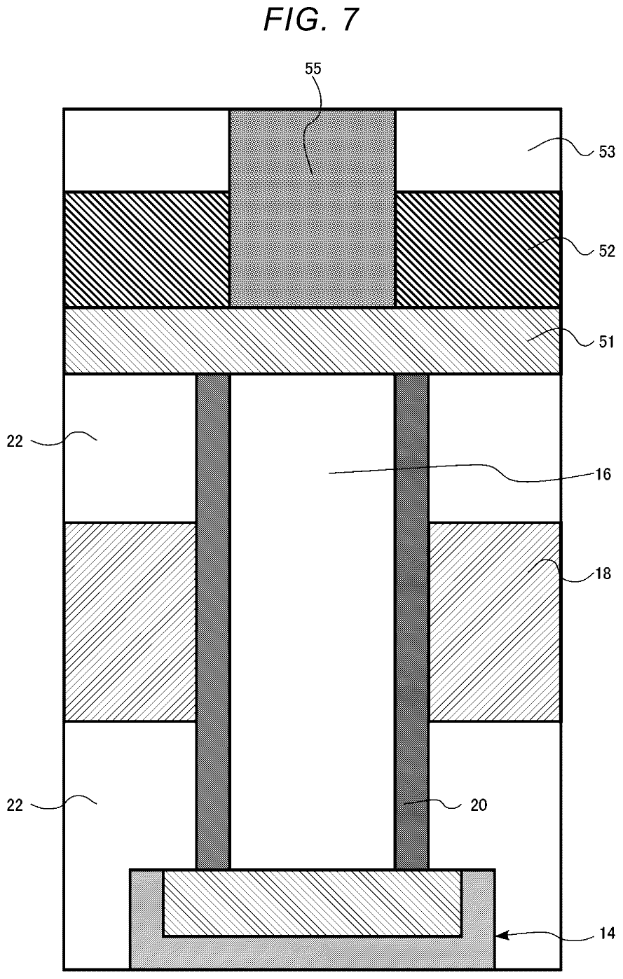

Next, an amorphous silicon film 55 is embedded in the opening 54 (FIG. 7). For example, the amorphous silicon film 55 is embedded in the opening 54 by depositing the amorphous silicon film 55 using the CVD method and removing the amorphous silicon film 55 on the silicon nitride film 53 using the chemical mechanical polishing method (CMP method).

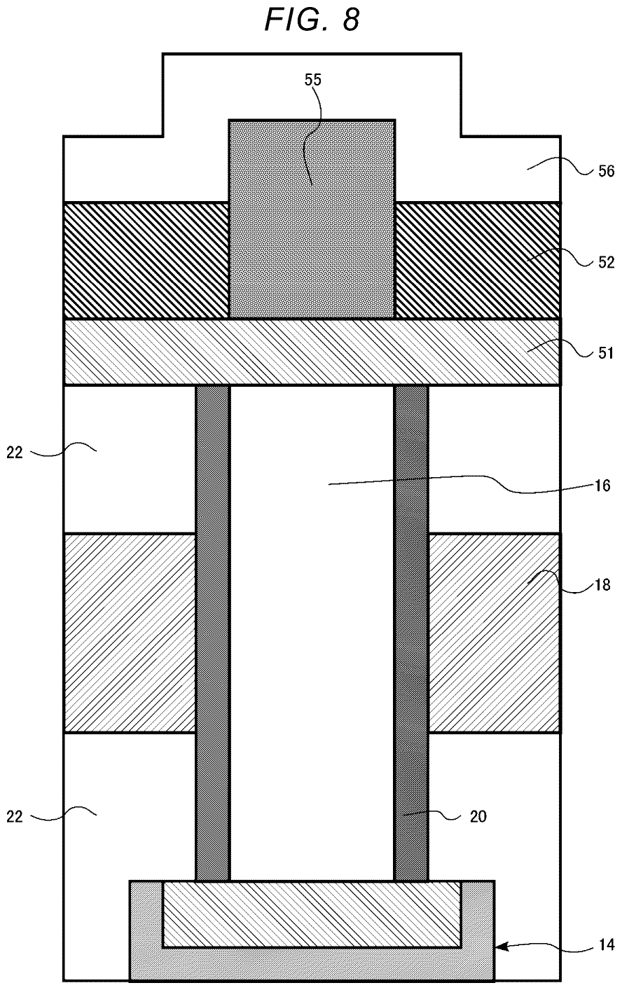

After the silicon nitride film 53 is removed, a first silicon oxide film 56 is formed on the amorphous silicon film 55 (FIG. 8). For example, the silicon nitride film 53 is removed by a wet etching method. For example, the first silicon oxide film 56 is formed by an ALD method (ALD-CVD method).

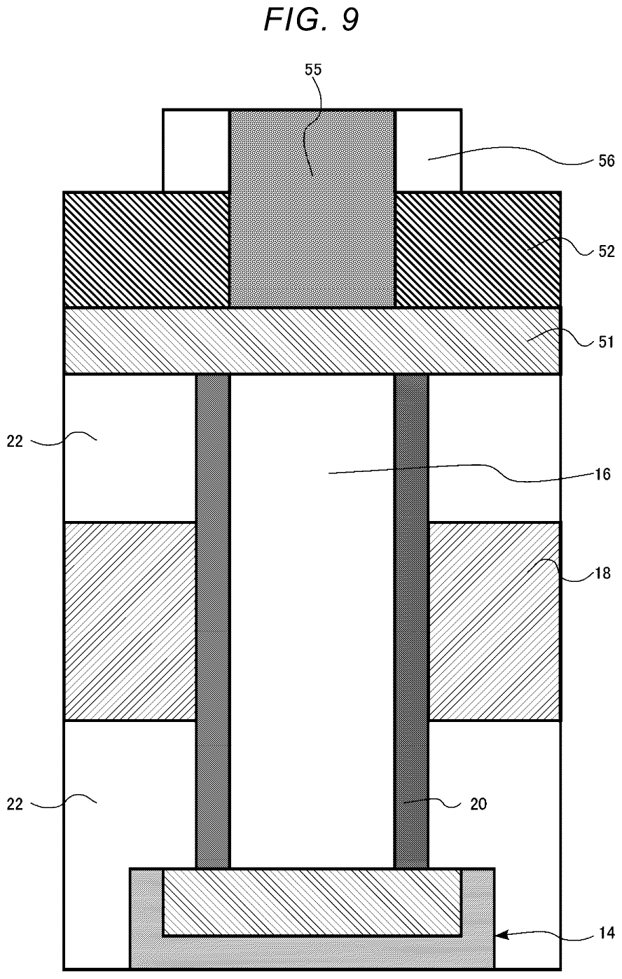

Next, a sidewall of the first silicon oxide film 56 is formed on a side surface of the amorphous silicon film 55 (FIG. 9). For example, the sidewall of the first silicon oxide film 56 is formed using the RIE method.

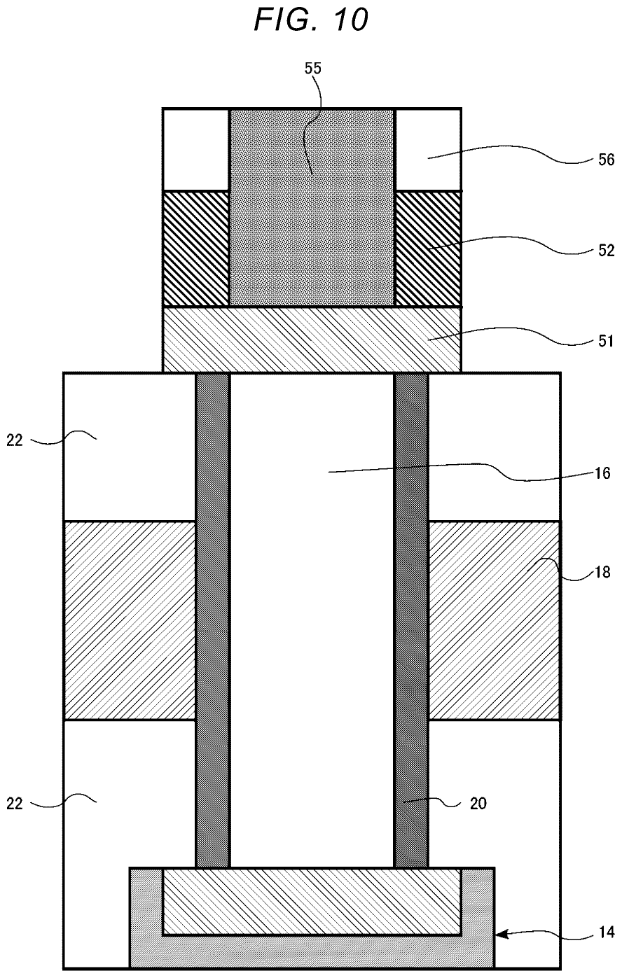

Next, a sidewall of the titanium oxide film 52 is formed on the side surface of the amorphous silicon film 55 (FIG. 10). For example, the sidewall of the titanium oxide film 52 is formed by etching the titanium oxide film 52 using the sidewall of the first silicon oxide film 56 as a mask material. At this time, the indium tin oxide film 51 is also etched simultaneously.

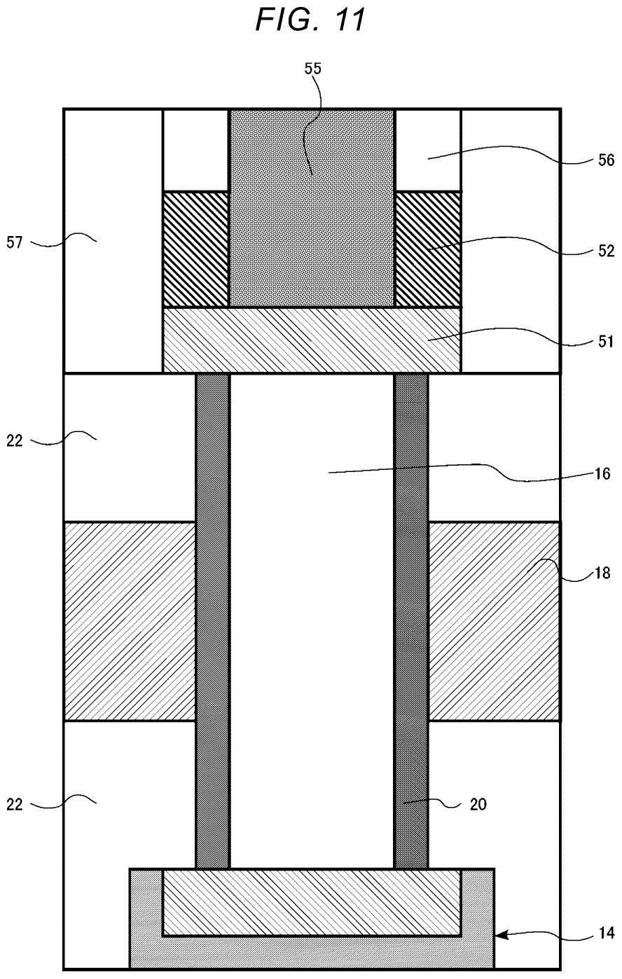

A second silicon oxide film 57 is formed around the indium tin oxide film 51, the titanium oxide film 52, and the first silicon oxide film 56 (FIG. 11). The second silicon oxide film 57 is formed by deposition using the CVD method and removal using the CMP method.

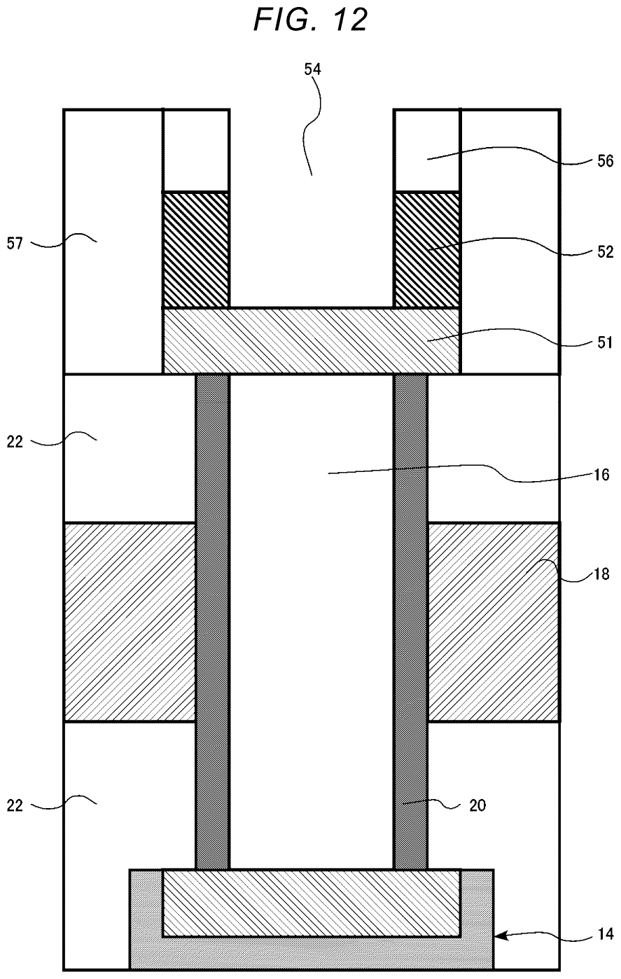

Next, the amorphous silicon film 55 embedded in the opening 54 is removed (FIG. 12). For example, the amorphous silicon film 55 is removed by a wet etching method.

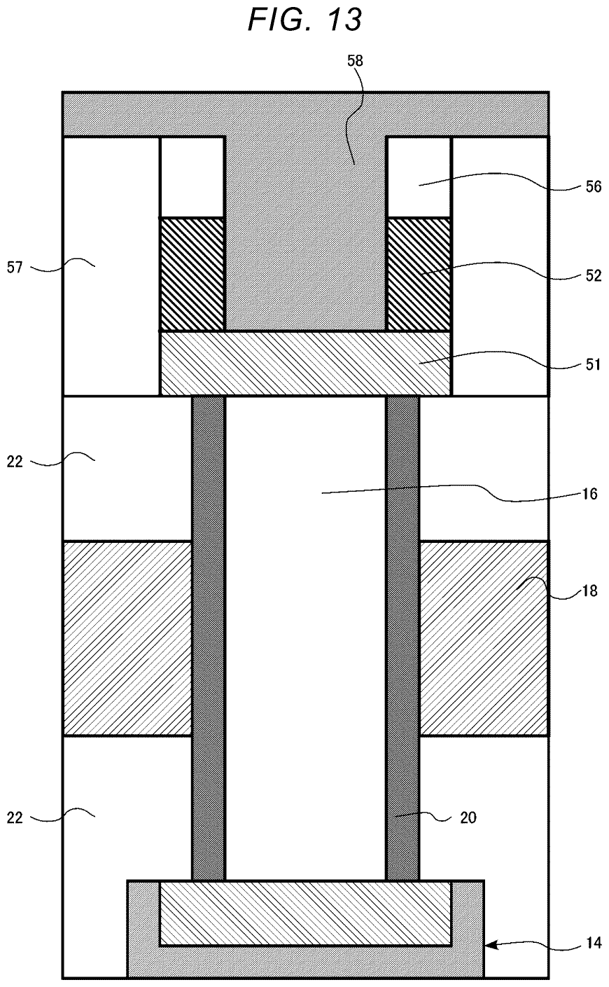

Next, a titanium nitride film 58 is embedded in the opening 54 (FIG. 13). For example, the titanium nitride film 58 is formed by the CVD method.

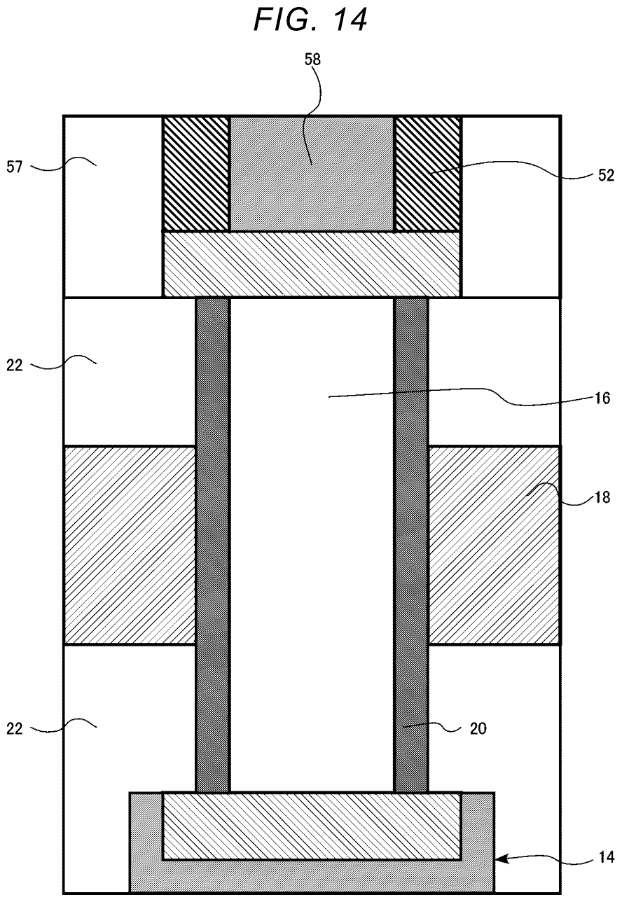

A part of the titanium nitride film 58, a part of the second silicon oxide film 57, and the first silicon oxide film 56 are removed to expose the titanium oxide film 52 on the surface (FIG. 14). For example, the part of the titanium nitride film 58, the part of the second silicon oxide film 57, and the first silicon oxide film 56 are removed using the CMP method.

Then, a tungsten film is formed and patterned on the titanium nitride film 58 to form the upper region 12d.

According to the manufacturing method described above, the transistor 100 illustrated in FIGS. 1, 2, 3, and 4 is manufactured.

Next, operations and effects of the semiconductor device according to the first embodiment will be described.

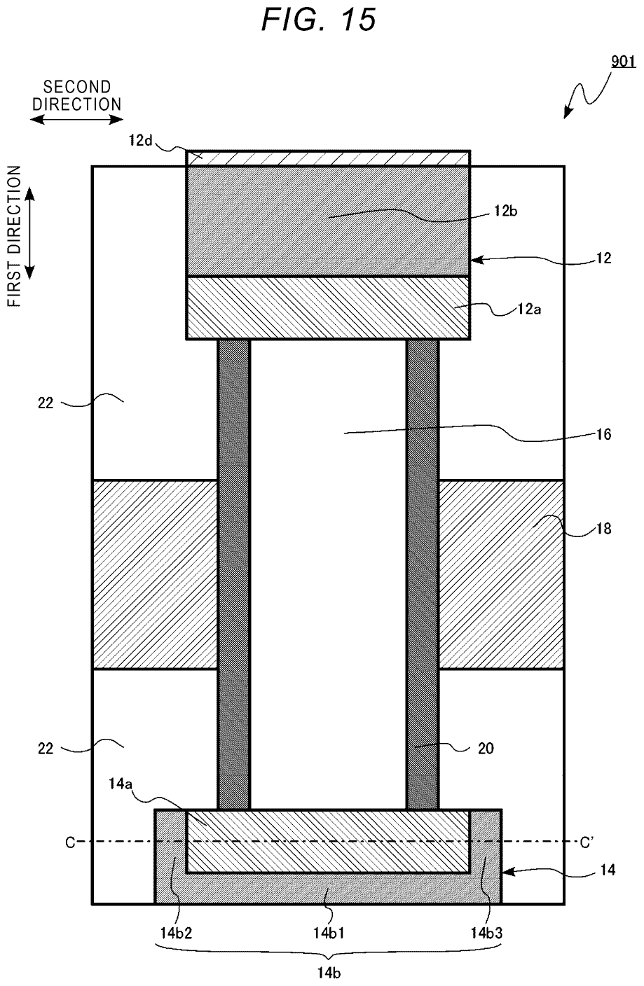

FIG. 15 is a schematic cross-sectional view of a semiconductor device according to a first comparative example. FIG. 15 is a view corresponding to FIG. 1 of the first embodiment.

The semiconductor device according to the first comparative example is a transistor 901. The transistor 901 according to the first comparative example is different from the transistor 100 according to the first embodiment in that the upper electrode 12 does not include the sidewall region 12c.

Hereinbelow, the problems of the transistor 901 according to the first comparative example will be described with reference to an example in which the first metal oxide region 12a of the upper electrode 12 is indium tin oxide, the first metal region 12b is titanium nitride, and the upper region 12d is tungsten.

The indium tin oxide as a material of the first metal oxide region 12a and the titanium nitride as a material of the first metal region 12b do not necessarily have high adhesion to each other. Accordingly, there is a risk of film peeling at the interface between indium tin oxide and titanium nitride during the operation of the transistor 901. For example, when film peeling occurs at the interface between indium tin oxide and titanium nitride, interface resistance is increased, the on-state resistance of the transistor 901 is increased, and the characteristics of the transistor 901 are deteriorated.

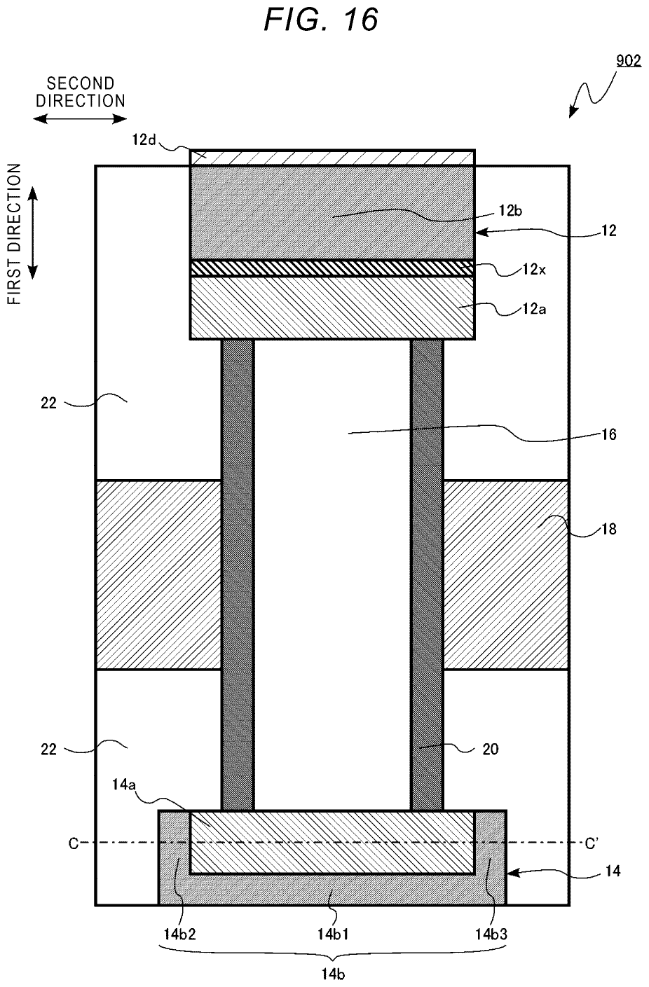

FIG. 16 is a schematic cross-sectional view of a semiconductor device according to a second comparative example. FIG. 16 is a view corresponding to FIG. 1 of the first embodiment.

The semiconductor device according to the second comparative example is a transistor 902. The transistor 902 according to the second comparative example is different from the transistor 100 according to the first embodiment in that the upper electrode 12 may not include the sidewall region 12c. The transistor 902 according to the second comparative example is different from the transistor 901 according to the first comparative example in that an interface region 12x is provided between the first metal oxide region 12a and the first metal region 12b.

A material of the interface region 12x is a material with high adhesion to a material of the first metal oxide region 12a. For example, when the first metal oxide region 12a is indium tin oxide, the material of the interface region 12x is titanium oxide having high adhesion to indium tin oxide. In addition, titanium oxide is a material with high adhesion to titanium nitride which is a material of the first metal region 12b.

Providing the interface region 12x having high adhesion to the material of the first metal oxide region 12a prevents film peeling during operation of the transistor 902. However, interface resistance between indium tin oxide and titanium oxide is higher than interface resistance between indium tin oxide and titanium nitride. Thus, on-state resistance as an initial characteristic of the transistor 902 is increased.

As described above, there is a trade-off relationship between preventing film peeling in the upper electrode 12 and reducing interface resistance.

In the transistor 100 according to the first embodiment, the upper electrode 12 includes the first metal region 12b in contact with the first metal oxide region 12a, and the sidewall region 12c in contact with the first metal oxide region 12a and surrounding the first metal region 12b.

The material of the first metal region 12b is a material with low interface resistance between itself and the material of the first metal oxide region 12a. For example, the material of the sidewall region 12c is a material with high bonding energy and high adhesion to the material of the first metal oxide region 12a.

For example, when the first metal oxide region 12a is indium tin oxide, the first metal region 12b is titanium nitride having low interface resistance with indium tin oxide. Further, the sidewall region 12c is titanium oxide having high bonding energy and high adhesion with indium tin oxide.

Thus, with the transistor 100 according to the first embodiment, it is possible to achieve both the prevention of film peeling in the upper electrode 12 and the reduction of interface resistance, enabling a transistor with excellent characteristics.

From the viewpoint of preventing film peeling in the upper electrode 12, the length (d2 in FIG. 1) of the first part 12c1 of the sidewall region 12c in the second direction is preferably at least one-fourth of the length (d1 in FIG. 1) of the first metal region 12b in the second direction, more preferably at least one-third, and further more preferably at least one-half. From the same viewpoint, the length (d3 in FIG. 1) of the second part 12c2 of the sidewall region 12c in the second direction is preferably at least one-fourth of the length (d1 in FIG. 1) of the first metal region 12b in the second direction, more preferably at least one-third, and further more preferably at least one-half.

From the viewpoint of reducing interface resistance in the upper electrode 12, the length (d2 in FIG. 1) of the first part 12c1 of the sidewall region 12c in the second direction is preferably at most three-fourths of the length (d1 in FIG. 1) of the first metal region 12b in the second direction, and more preferably at most two-thirds. From the same viewpoint, the length (d3 in FIG. 1) of the second part 12c2 of the sidewall region 12c in the second direction is preferably at most three-fourths of the length (d1 in FIG. 1) of the first metal region 12b in the second direction, and more preferably at most two-thirds.

For the transistor 100 according to the first embodiment, it is considered that a material with a lower interface resistance to the material of the second metal oxide region 14a is selected as a material for the second metal region 14b to reduce interface resistance of the lower electrode 14. In this case, as in the case of the upper electrode 12, the adhesion between the material of the second metal oxide region 14a and the material of the second metal region 14b decreases, raising concerns about film peeling.

However, the lower electrode 14 is different from the upper electrode 12 in that the second metal oxide region 14a is surrounded by the second metal region 14b in a cross-section perpendicular to the first direction illustrated in FIG. 4. Accordingly, the adhesion between the second metal oxide region 14a and the second metal region 14b is improved, and film peeling can be prevented. Accordingly, even if the material of the second metal oxide region 14a is the same as the material of the first metal oxide region 12a, and the material of the second metal region 14b is the same as the material of the first metal region 12b, film peeling in the lower electrode 14 can be prevented by adopting a different structure from the upper electrode 12 and not providing a region corresponding to the sidewall region 12c.

For example, when manufacturing the transistor 100 according to the first embodiment, if oxygen (O) is excessively diffused into the first metal region 12b during thermal treatment in an oxidizing atmosphere in the middle of manufacture after the formation of the upper electrode, there is a concern that the oxidation of the material of the first metal region 12b may progress, resulting in an increase in the resistance of the upper electrode 12.

The first metal region 12b of the transistor 100 according to the first embodiment includes the internal region 12bx and the external region 12by. The oxygen concentration in the external region 12by is higher than the oxygen concentration in the internal region 12bx. In other words, the oxygen concentration in the internal region 12bx is lower than the oxygen concentration in the external region 12by.

In the internal region 12bx with a low oxygen concentration prevents the increase in resistance due to the oxidation of the first metal region 12b. Accordingly, the transistor 100 according to the first embodiment prevents the increase in resistance of the upper electrode 12, enabling a transistor with low on-state resistance and excellent characteristics.

From the viewpoint of preventing the increase in resistance due to oxidation of the first metal region 12b of the transistor 100 according to the first embodiment, it is preferable that the sidewall region 12c surrounding the first metal region 12b includes a material with low oxygen permeability, such as silicon oxide or aluminum oxide. Accordingly, the first element of the sidewall region 12c is preferably silicon (Si) or aluminum (Al).

For example, when silicon oxide is contained in the sidewall region 12c and silicon oxide is also contained in the interlayer insulating layer 22, the density of silicon oxide contained in the sidewall region 12c is preferably higher than the density of silicon oxide contained in the interlayer insulating layer 22. In other words, the density of the sidewall region 12c is preferably higher than the density of the interlayer insulating layer 22. In other words, when the first element is silicon (Si) and the interlayer insulating layer 22 contains silicon (Si) and oxygen (O), the density of the sidewall region 12c is preferably higher than the density of the interlayer insulating layer 22.

The high density of silicon oxide contained in the sidewall region 12c can further reduce the permeation of oxygen to the first metal region 12b.

From the viewpoint of preventing oxidation of the first metal region 12b, the sidewall region 12c is preferably brought into contact with the upper region 12d.

According to the first embodiment, the semiconductor device having excellent transistor characteristics can be achieved.

### Second Embodiment

A semiconductor device according to a second embodiment includes a first electrode, a second electrode, an oxide semiconductor layer provided between the first electrode and the second electrode, a gate electrode opposite to the oxide semiconductor layer, and a gate insulation layer provided between the gate electrode and the oxide semiconductor layer. The first electrode includes a first region, a second region, and a third region. The first region is provided between the second region and the oxide semiconductor layer, is in contact with the oxide semiconductor layer and the second region, and contains a first metal element and oxygen (O), and the first metal element is at least one element selected from a group including indium (In), tin (Sn), zinc (Zn), tantalum (Ta) and tungsten (W). The second region contains a second metal element and contains or does not contain nitrogen (N), and the second metal element is one element selected from a group including titanium (Ti), tungsten (W), molybdenum (Mo) and tantalum (Ta). The third region is in contact with the first region and the second region and includes a first part and a second part, the second region is provided between the first part and the second part in a second direction perpendicular to a first direction connecting the first electrode and the second electrode, and the third region contains silicon (Si) and nitrogen (N), silicon (Si) and oxygen (O) and nitrogen (N), aluminum (Al) and nitrogen (N), or tantalum (Ta) and nitrogen (N). The semiconductor device according to the second embodiment is different from the semiconductor device according to the first embodiment in that the third region contains silicon (Si) and nitrogen (N), silicon (Si) and oxygen (O) and nitrogen (N), aluminum (Al) and nitrogen (N), or tantalum (Ta) and nitrogen (N). In the following description, some overlapping descriptions with the semiconductor device according to the first embodiment may be omitted.

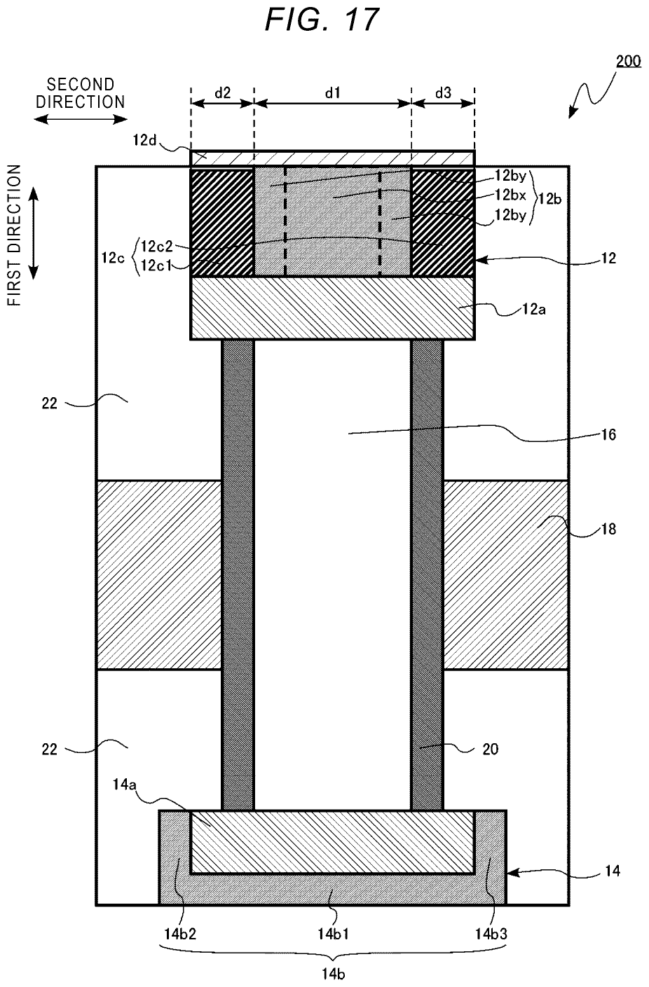

FIG. 17 is a schematic cross-sectional view illustrating the semiconductor device according to the second embodiment. FIG. 17 is a view corresponding to FIG. 1 of the first embodiment.

The semiconductor device according to the second embodiment is a transistor 200. The transistor 200 is different from the transistor 100 according to the first embodiment in that the sidewall region 12c of the upper electrode 12 includes silicon (Si) and nitrogen (N).

The sidewall region 12c contains silicon (Si) and nitrogen (N), silicon (Si) and oxygen (O) and nitrogen (N), aluminum (Al) and nitrogen (N), or tantalum (Ta) and nitrogen (N). The sidewall region 12c contains at least one combination of elements selected from a group including a first combination of silicon (Si) and nitrogen (N), a second combination of silicon (Si) and oxygen (O) and nitrogen (N), a third combination of aluminum (Al) and nitrogen (N), and a fourth combination of tantalum (Ta) and nitrogen (N). For example, the sidewall region 12c contains silicon nitride, silicon oxynitride, aluminum nitride, or tantalum nitride. For example, the sidewall region 12c is silicon nitride, silicon oxynitride, aluminum nitride, or tantalum nitride.

For example, the interlayer insulating layer 22 surrounds the upper electrode 12 in a cross-section perpendicular to the first direction. For example, the interlayer insulating layer 22 surrounds the sidewall region 12c of the upper electrode 12. For example, the interlayer insulating layer 22 is in contact with the sidewall region 12c.

The interlayer insulating layer 22 is an insulator. For example, the interlayer insulating layer 22 is oxide, nitride, or oxynitride. For example, the interlayer insulating layer 22 contains silicon (Si) and oxygen (O). For example, the interlayer insulating layer 22 contains silicon oxide. For example, the interlayer insulating layer 22 is silicon oxide.

For example, the chemical composition of the interlayer insulating layer 22 is different from the chemical composition of the sidewall region 12c of the upper electrode 12.

Next, operations and effects of the semiconductor device according to the second embodiment will be described.

When manufacturing the transistor 200 according to the second embodiment, if oxygen (O) is excessively diffused into the first metal region 12b during thermal treatment in an oxidizing atmosphere in the middle of manufacture after the formation of the upper electrode, there is a concern that the oxidation of the material of the first metal region 12b may progress, resulting in an increase in the resistance of the upper electrode 12.

In the transistor 200 according to the second embodiment, materials having low oxygen permeability, that is, materials including silicon (Si) and nitrogen (N), silicon (Si) and oxygen (O) and nitrogen (N), aluminum (Al) and nitrogen (N), or tantalum (Ta) and nitrogen (N) are used for the sidewall region 12c. For example, the sidewall region 12c contains silicon nitride, silicon oxynitride, aluminum nitride, or tantalum nitride. In the transistor 200 according to the second embodiment, using a material with low oxygen permeability for the sidewall region 12c prevents oxidation of the material of the first metal region 12b.

The first metal region 12b of the transistor 200 according to the second embodiment includes the internal region 12bx and the external region 12by. The oxygen concentration in the external region 12by is higher than the oxygen concentration in the internal region 12bx. In other words, the oxygen concentration in the internal region 12bx is lower than the oxygen concentration in the external region 12by. In the internal region 12bx with a low oxygen concentration prevents the increase in resistance due to the oxidation of the first metal region 12b.

From the viewpoint of preventing oxidation of the first metal region 12b, the sidewall region 12c is preferably brought into contact with the upper region 12d.

From the viewpoint of preventing oxidation of the first metal region 12b, the length (d2 in FIG. 17) of the first part 12c1 of the sidewall region 12c in the second direction is preferably at least one-fourth of the length (d1 in FIG. 17) of the first metal region 12b in the second direction, more preferably at least one-third, and further more preferably at least one-half. From the same viewpoint, the length of the second part 12c2 of the sidewall region 12c in the second direction (d3 in FIG. 17) is preferably at least one-fourth of the length (d1 in FIG. 17) of the first metal region 12b in the second direction, more preferably at least one-third, and further more preferably at least one-half.

From the viewpoint of reducing interface resistance in the upper electrode 12, the length (d2 in FIG. 17) of the first part 12c1 of the sidewall region 12c in the second direction is preferably at most three-fourths of the length (d1 in FIG. 17) of the first metal region 12b in the second direction, and more preferably at most two-thirds. From the same viewpoint, the length (d3 in FIG. 17) of the second part 12c2 of the sidewall region 12c in the second direction is preferably at most three-fourths of the length (d1 in FIG. 17) of the first metal region 12b in the second direction, and more preferably at most two-thirds.

According to the second embodiment, the semiconductor device having excellent transistor characteristics can be achieved.

### Third Embodiment

A semiconductor storage device according to a third embodiment includes the semiconductor device according to the first embodiment and a capacitor electrically connected to the second electrode.

The semiconductor storage device according to the third embodiment is a semiconductor memory 300. The semiconductor storage device according to the third embodiment is DRAM. The semiconductor memory 300 uses the transistor 100 according to the first embodiment as a switching transistor of a DRAM memory cell.

In the following description, some overlapping descriptions with the first embodiment will be omitted.

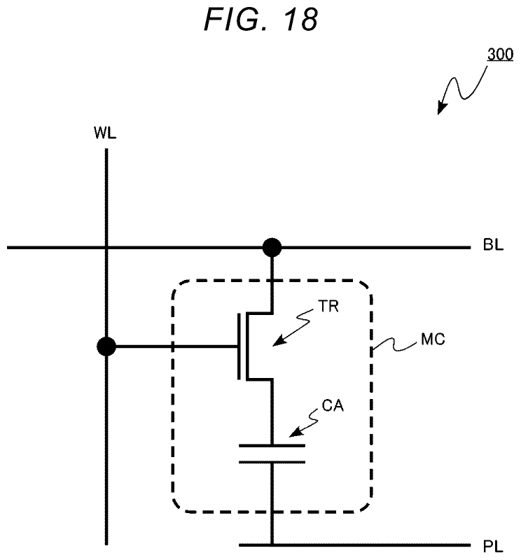

FIG. 18 is an equivalent circuit diagram illustrating the semiconductor storage device according to the third embodiment. Although FIG. 18 illustrates an example of a single memory cell MC, aspects are not limited thereto. For example, a plurality of memory cells MC may be provided in an array configuration.

The semiconductor memory 300 includes a memory cell MC, a word line WL, a bit line BL, and a plate line PL. The memory cell MC includes a switching transistor TR and a capacitor CA. In FIG. 18, a region surrounded by a dotted line is the memory cell MC.

The word line WL is electrically connected to the gate electrode of the switching transistor TR. The bit line BL is electrically connected to one side of the source-drain electrodes of the switching transistor TR. One electrode of the capacitor CA is electrically connected to the other side of the source-drain electrodes of the switching transistor TR. The other electrode of the capacitor CA is connected to the plate line PL.

The memory cell MC stores data by accumulating charges in the capacitor CA. Writing and reading data is performed by operating the switching transistor TR.

For example, by turning on the switching transistor TR while applying a desired voltage to the bit line BL, data is written into the memory cell MC.

Further, for example, by turning on the switching transistor TR, change in the voltage of the bit line BL corresponding to the charge amount accumulated in the capacitor is detected and the data of the memory cell MC is read.

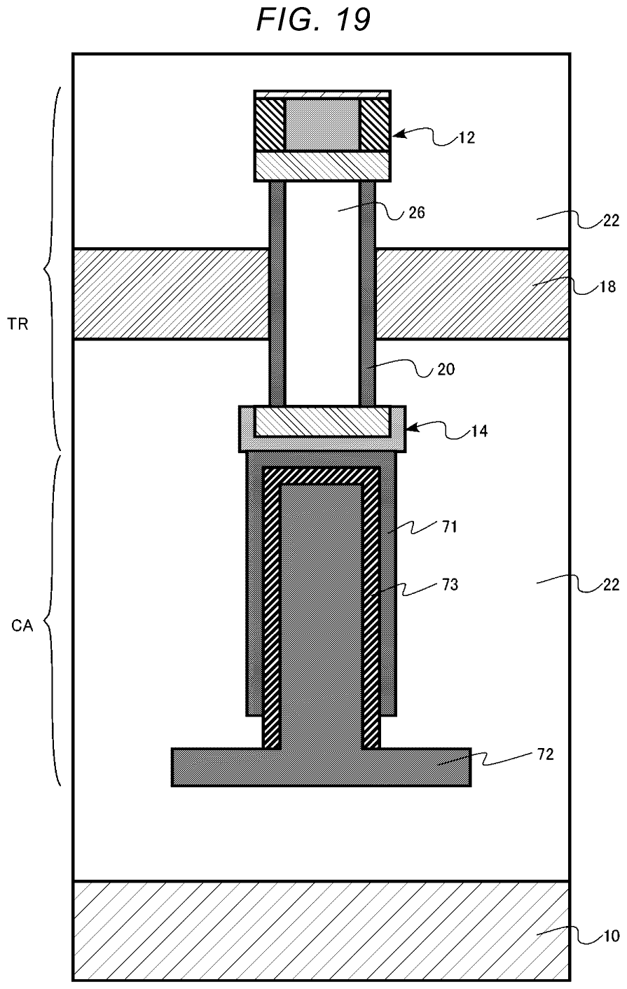

FIG. 19 is a schematic cross-sectional view of the semiconductor storage device according to the third embodiment. FIG. 19 illustrates a cross-section of the memory cell MC of the semiconductor memory 300.

The semiconductor memory 300 includes a silicon substrate 10, the switching transistor TR, and the capacitor CA.

The switching transistor TR has the same structure as that of the transistor 100 according to the first embodiment.

The capacitor CA is provided between the silicon substrate 10 and the switching transistor TR. The capacitor CA is provided between the silicon substrate 10 and the lower electrode 14. The capacitor CA is electrically connected to the lower electrode 14.

The capacitor CA includes a cell electrode 71, a plate electrode 72 and a capacitor insulating film 73. The cell electrode 71 is electrically connected to the lower electrode 14.

For example, the cell electrode 71 and the plate electrode 72 are titanium nitride. For example, the capacitor insulating film 73 has a stacked structure of zirconium oxide, aluminum oxide, and zirconium oxide.

For example, the gate electrode 18 is electrically connected to a word line WL (not illustrated). For example, the upper electrode 12 is electrically connected to a bit line BL (not illustrated). For example, the plate electrode 72 is connected to a plate line PL (not illustrated).

The semiconductor memory 300 applies an oxide semiconductor transistor with extremely low channel leakage current during off-operation to the switching transistor TR. Therefore, a DRAM with excellent charge retention characteristics is achieved.

In addition, the switching transistor TR of the semiconductor memory 300 is the transistor 100 with excellent characteristics according to the first embodiment. As a result, the semiconductor memory 300 having excellent operating characteristics can be achieved.

The third embodiment is described above by referring to an example of the semiconductor memory using the transistor according to the first embodiment, but the semiconductor memory according to embodiments of the disclosure may also use the transistor according to the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first electrode;
a second electrode;
an oxide semiconductor layer extending between the first electrode and the second electrode along a first direction;
a gate electrode provided next to the oxide semiconductor layer; and
a gate insulation layer provided between the gate electrode and the oxide semiconductor layer, wherein
the first electrode includes a first region, a second region, and a third region,
the first region is provided between the second region and the oxide semiconductor layer, and includes a first metal element and oxygen (O), and the first metal element includes at least one of indium (In), tin (Sn), zinc (Zn), tantalum (Ta) or tungsten (W),
the second region includes a second metal element and includes or does not include nitrogen (N), and the second metal element includes one of titanium (Ti), tungsten (W), molybdenum (Mo) or tantalum (Ta), and
the third region is in contact with the first region and the second region and includes a first part and a second part, the second region is provided between the first part and the second part in a second direction perpendicular to the first direction, the third region includes a first element and oxygen (O), and the first element includes at least one of titanium (Ti), aluminum (Al), zirconium (Zr), hafnium (Hf), or silicon (Si).

2. The semiconductor device according to claim 1, wherein
the first electrode further includes a fourth region,
the second region is provided between the first region and the fourth region, and the fourth region is in contact with the second region,
the third region is provided between the first region and the fourth region, and the fourth region is in contact with the third region, and
the fourth region includes tungsten (W) or titanium (Ti).

3. The semiconductor device according to claim 1, wherein the third region surrounds the second region.

4. The semiconductor device according to claim 1, wherein the first element is silicon (Si) or aluminum (Al).

5. The semiconductor device according to claim 1, further comprising an insulating layer surrounding the third region.

6. The semiconductor device according to claim 5, wherein, when the first element is silicon (Si) and the insulating layer contains silicon (Si) and oxygen (O), a density of the third region is higher than a density of the insulating layer.

7. The semiconductor device according to claim 1, wherein the second region includes an internal region and an external region, the internal region is provided between a part of the external region and another part in the second direction, the external region includes oxygen (O), the internal region includes or does not include oxygen (O), and an oxygen concentration in the external region is higher than an oxygen concentration in the internal region.

8. The semiconductor device according to claim 1, wherein the first metal element is indium (In) and tin (Sn), the second metal element is titanium (Ti), the second region contains nitrogen (N), and the first element is titanium (Ti).

9. The semiconductor device according to claim 1, wherein a length of the first part in the second direction is at least one-fourth of a length of the second region in the second direction, and a length of the second part in the second direction is at least one-fourth of the length of the second region in the second direction.

10. The semiconductor device according to claim 1, wherein the gate electrode surrounds the oxide semiconductor layer.

11. The semiconductor device according to claim 1, wherein
the second electrode includes a fifth region and a sixth region,
the fifth region is provided between the oxide semiconductor layer and the sixth region, and includes a third metal element and oxygen (O), and the third metal element includes at least one of indium (In), tin (Sn), zinc (Zn), tantalum (Ta) or tungsten (W),
the sixth region includes a third part, a fourth part, and a fifth part, the fifth region is located between the third part and the oxide semiconductor layer, the fifth region is located between the fourth part and the fifth part in the second direction, the fifth region is in contact with the third part, the fourth part, and the fifth part, the sixth region includes a fourth metal element and includes or does not include nitrogen (N), and the fourth metal element includes one of titanium (Ti), tungsten (W), molybdenum (Mo) or tantalum (Ta).

12. The semiconductor device according to claim 11, wherein the first metal element and the third metal element are the same elements, and the second metal element and the fourth metal element are the same elements.

13. A semiconductor storage device, comprising:
the semiconductor device according to claim 1; and
a capacitor electrically connected to the second electrode.

14. A semiconductor device, comprising:
a first electrode;
a second electrode;
an oxide semiconductor layer extending between the first electrode and the second electrode along a first direction;
a gate electrode disposed next to the oxide semiconductor layer; and
a gate insulation layer provided between the gate electrode and the oxide semiconductor layer, wherein
the first electrode includes a first region, a second region, and a third region,
the first region is provided between the second region and the oxide semiconductor layer, and includes a first metal element and oxygen (O), and the first metal element includes at least one of indium (In), tin (Sn), zinc (Zn), tantalum (Ta) or tungsten (W),
the second region contains a second metal element and includes or does not include nitrogen (N), and the second metal element includes one of titanium (Ti), tungsten (W), molybdenum (Mo) or tantalum (Ta), and
the third region is in contact with the first region and the second region and includes a first part and a second part, the second region is provided between the first part and the second part in a second direction perpendicular to the first direction, and the third region includes silicon (Si) and nitrogen (N), silicon (Si) and oxygen (O) and nitrogen (N), aluminum (Al) and nitrogen (N), or tantalum (Ta) and nitrogen (N).

15. The semiconductor device according to claim 14, wherein
the first electrode further includes a fourth region,
the second region is provided between the first region and the fourth region, and the fourth region is in contact with the second region,
the third region is provided between the first region and the fourth region, and the fourth region is in contact with the third region, and
the fourth region includes tungsten (W) or titanium (Ti).

16. The semiconductor device according to claim 14, wherein the third region surrounds the second region.

17. The semiconductor device according to claim 14, further comprising an insulating layer surrounding the third region and having a different chemical composition from a chemical composition of the third region.

18. The semiconductor device according to claim 14, wherein the second region includes an internal region and an external region, the internal region is provided between a part of the external region and another part in the second direction, the external region includes oxygen (O), the internal region includes or does not include oxygen (O), and an oxygen concentration in the external region is higher than an oxygen concentration in the internal region.

19. The semiconductor device according to claim 14, wherein the first metal element is indium (In) and tin (Sn), the second metal element is titanium (Ti), and the second region contains nitrogen (N).

20. The semiconductor device according to claim 14, wherein a length of the first part in the second direction is at least one-fourth of a length of the second region in the second direction, and a length of the second part in the second direction is at least one-fourth of the length of the second region in the second direction.

21. The semiconductor device according to claim 14, wherein the gate electrode surrounds the oxide semiconductor layer.

22. The semiconductor device according to claim 14, wherein
the second electrode includes a fifth region and a sixth region,
the fifth region is provided between the oxide semiconductor layer and the sixth region, is in contact with the oxide semiconductor layer and the sixth region, and includes a third metal element and oxygen (O), and the third metal element includes at least one of indium (In), tin (Sn), zinc (Zn), tantalum (Ta) or tungsten (W), and
the sixth region includes a third part, a fourth part, and a fifth part, the fifth region is located between the third part and the oxide semiconductor layer, the fifth region is located between the fourth part and the fifth part in the second direction, the fifth region is in contact with the third part, the fourth part, and the fifth part, the sixth region includes a fourth metal element and includes or does not include nitrogen (N), and the fourth metal element includes one of titanium (Ti), tungsten (W), molybdenum (Mo) or tantalum (Ta).

23. The semiconductor device according to claim 22, wherein the first metal element and the third metal element are the same elements, and the second metal element and the fourth metal element are the same elements.

24. A semiconductor storage device, comprising:
the semiconductor device according to claim 14; and
a capacitor electrically connected to the second electrode.
